(19) United States
(12) Patent Application Publication
(10) Pub. No.: US 2002/0030227 A1
(43) Pub. Date: Mar. 14, 2002

(54) Strained-silicon diffused metal oxide semiconductor field effect transistors

(76) Inventors: Mayank T. Bulsara, Cambridge, MA (US); Eugene A. Fitzgerald, Windham, NH (US)

Correspondence Address: Samuels, Gauthier & Stevens LLP, 225 Franklin Street, Suite 3300, Boston, MA, 02110, US

(21) Appl. No.: 09/764,547

(22) Filed: Jan. 18, 2001

Related U.S. Application Data
(60) Provisional application No. 60/177,099, filed on Jan. 20, 2000.

(51) Int. Cl. H01L 31/0336

(52) U.S. Cl. 257/346

(57) ABSTRACT

A DMOS field effect transistor fabricated from a SiGe heterostructure and a method of fabricating same. The heterostructure includes a strained Si layer on a relaxed, low dislocation density SiGe template. In an exemplary embodiment, the DMOS FET includes a SiGe/Si heterostructure on top of a bulk Si substrate. The heterostructure includes a SiGe graded layer, a SiGe cap of uniform composition layer, and a strained Si channel layer. In accordance with another embodiment, the invention provides a heterostructure for a DMOS transistor, and method of fabricating same, including a monocrystalline Si substrate, a relaxed uniform composition SiGe layer on the substrate; a first strained-Si channel layer on the uniform composition SiGe layer, a SiGe cap layer on the strained-Si channel layer, and a second strained-Si layer on the cap layer.

### PRIORITY INFORMATION

This application claims priority from provisional application Ser. No. 60/177,099 filed Jan. 20, 2000.

### BACKGROUND OF THE INVENTION

The invention relates to strained-Si diffused metal oxide semiconductor (DMOS) field effect transistors (FETs).

The receiving/transmitting systems in the wireless communications industry form the backbone of what has become an essential communications network throughout the world. To sustain the continued growth of the wireless communications industry in terms of number of users, data transfer rates, and commercial potential, the essential microelectronic components that are placed in the receiving/transmitting systems must perform at higher levels at lower cost.

GaAs and other III-V compound semiconductors provide the necessary performance in terms of power and speed; however, they do not provide the volume-cost curve to sustain the continued expansion of the wireless communications industry. For this reason, Si microelectronics, which offer compelling economics compared to other semiconductor technologies, have invaded market space previously occupied by III-V compound microelectronics. Different Si technologies are implemented at different parts of the communications backbone. For analog applications that require operation at high voltage, i.e., the devices must have a large breakdown voltage, the Si diffused metal oxide semiconductor (DMOS) transistor is commonly implemented.

A schematic block diagram of a DMOS transistor 100 is shown in FIG. 1. The key features of this device, as compared to standard Si metal-oxide-semiconductor field effect transistors (MOSFET) or bipolar junction transistors (BJT), are the diffused channel region 102 close to the source 104 and the extended drain 106 (collectively, these two regions can be referred to as the channel region). The combination gives DMOS transistors the ability to operate at high frequency and withstand a large voltage drop between the source and the drain for high power operation. Note that DMOS transistors also have configurations where the terminals for the device are not all on the surface.

To make a distinction between the different configurations, the device depicted in FIG. 1 is commonly referred to as a lateral DMOS (LDMOS) transistor. A device with its terminals on the front and backside of the wafer is referred to as a vertical DMOS (VDMOS) transistor. The descriptions and embodiments of the invention are best described in the LDMOS configuration. Even within the LDMOS category, there are further variations on the LDMOS transistor that incorporate different doping concentrations in the channel region. With reference to FIGS. 2A-2C, there are shown schematics of different doping profiles in an LDMOS transistor channel. FIGS. 2A and 2B show asymmetric doping profiles, and FIG. 2C shows a symmetric doping profile.

Although Si-based devices, including Si DMOS, have supplanted III-V compound devices in many microelectronics markets, the inherent speed limitations of Si still prevent it from displacing III-V compound devices in a number of very high-speed applications. To address the limitations of Si, novel device heterostructures can be implemented with SiGe alloys to allow Si to extend its roadmap and continue to provide better performance in an economical manner, an essential combination for future communications systems.

FIG. 3 is a schematic of the wireless communications spectrum with a snapshot of current materials technologies and anticipated materials technologies. SiGe-based electronics are predicted to play a heavy role in future wireless communications electronics.

### SUMMARY OF THE INVENTION

The invention provides a DMOS field effect transistor fabricated from a SiGe heterostructure and a method of fabricating same. The heterostructure includes a strained Si layer on a relaxed, low dislocation density SiGe template. In an exemplary embodiment, the DMOS FET includes a SiGe/Si heterostructure on top of a bulk Si substrate. The heterostructure includes a SiGe graded layer, a SiGe cap of uniform composition layer, and a strained Si channel layer.

In accordance with one embodiment, the invention provides a heterostructure for a DMOS transistor, and method of fabricating same, including a monocrystalline Si substrate, a relaxed SiGe uniform composition layer on the substrate, and a strained-Si channel layer on the uniform composition layer. The heterostructure can be implemented into an integrated circuit.

In accordance with another embodiment, the invention provides a heterostructure for a (DMOS) transistor, and method of fabricating same, including a monocrystalline Si substrate, a relaxed SiGe uniform composition layer on the substrate, a first strained-Si channel layer on the uniform composition layer, a SiGe cap layer on the strained-Si channel layer, and a second strained-Si layer on the cap layer.

### BRIEF DESCRIPTION OF THE DRAWINGS

FIG. 1 is a schematic block diagram of a DMOS transistor;

FIGS. 2A-2C are schematics of different doping profiles in an LDMOS transistor channel;

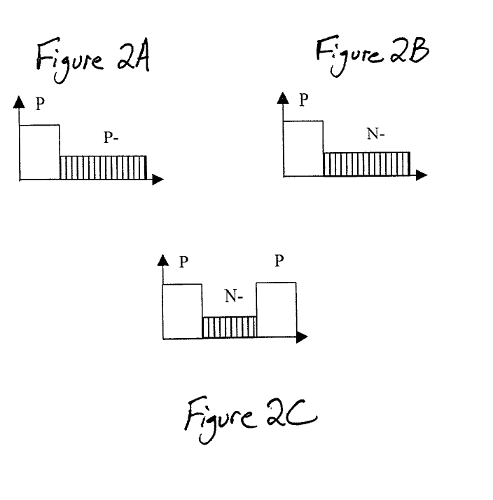

FIG. 3 is a schematic of the wireless communications spectrum with a snapshot of current materials technologies and anticipated materials technologies;

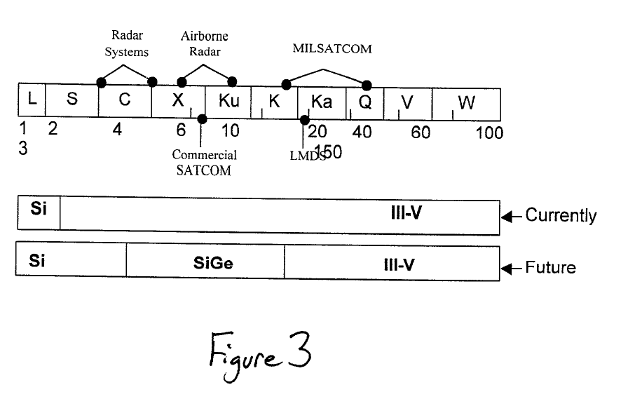

FIG. 4 is a schematic block diagram of an exemplary embodiment of a DMOS FET in accordance with the invention;

FIG. 5 is a schematic depiction of the band offset for strained Si on relaxed SiGe;

FIG. 6 is a schematic depiction of the conduction band of strained Si;

FIGS. 7A and 7B are graphs showing mobility enhancements vs. effective field for electrons and holes, for strained silicon on Si₁₋ₓGeₓ for x=10-30%, respectively;

FIG. 8 is a schematic equivalent circuit diagram of an enhancement/depletion mode model DMOS transistor 80 in accordance with an exemplary embodiment of the invention;

FIG. 9 is a graph of the transconductance for a LDMOS transistor with strained-Si (ε-Si) and bulk Si with a saturation condition in both the enhancement mode and depletion mode regime;

FIG. 10 is a graph of the transconductance for a LDMOS transistor with strained-Si and bulk Si with a saturation condition only in the depletion mode regime;

FIG. 11 is a schematic block diagram of an exemplary embodiment of a strained Si DMOS transistor in accordance with the invention;

FIGS. 12A and 12B are schematic block diagrams of alternative exemplary embodiments of LDMOS transistor structures in accordance with the invention; and

FIG. 13 is a schematic block diagram of an exemplary embodiment of a buried channel LDMOS transistor device structure 130 in accordance with the invention.

### DETAILED DESCRIPTION OF THE INVENTION

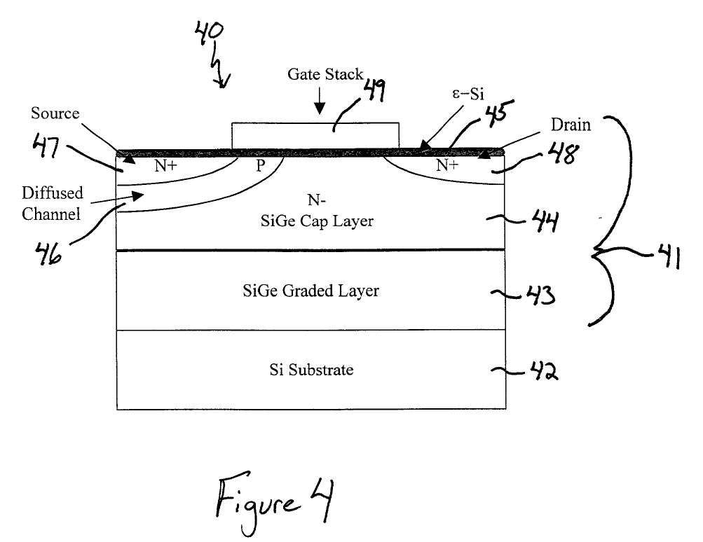

The invention is a DMOS field effect transistor fabricated from a SiGe heterostructure, including a strained Si layer on a relaxed, low dislocation density SiGe template. FIG. 4 is a schematic block diagram of an exemplary embodiment of a DMOS FET 40 in accordance with the invention. The FET includes a SiGe/Si heterostructure 41 on top of a bulk Si substrate 42. The heterostructure includes a SiGe graded layer 43, a SiGe cap of uniform composition layer 44, and a strained Si (ε-Si) channel layer 45. The device also includes a diffused channel 46, a source 47, a drain 48, and a gate stack 49.

The layers are grown epitaxially with a technique such as low-pressure chemical vapor deposition (LPCVD). The SiGe graded layer 43 employs technology developed to engineer the lattice constant of Si. See, for example, E. A. Fitzgerald et. al., J. Vac. Sci. Tech. B 10, 1807 (1992), incorporated herein by reference. The SiGe cap layer 44 provides a virtual substrate that is removed from the defects in the graded layer and thus allows reliable device layer operation. The strained Si layer 45 on top of the SiGe cap is under tension because the equilibrium lattice constant of Si is less than that of SiGe. It will be appreciated that the thickness of the Si layer is limited due to critical thickness constraints.

The tensile strain breaks the degeneracy of the Si conduction band so that only two valleys are occupied instead of six. This conduction band split results in a very high in-plane mobility in the strained Si layer (˜2900 cm²/V-sec with 10¹¹-10¹² cm⁻² electron densities, closer to 1000 cm²/V-sec with >10¹² cm⁻² electron densities). By using the high mobility, strained silicon for the channel region of a DMOS device, the device speed can be improved by 20-80% at constant gate length. Unlike GaAs high mobility technologies, strained silicon DMOS devices can be fabricated with standard silicon DMOS processing methods and tools. This compatibility allows for significant performance enhancement at low cost.

Semiconductor heterostructures have been utilized in various semiconductor devices and materials systems (AlGaAs/GaAs for semiconductor lasers and InGaAs/GaAs heterojunction field effect transistors). However, most of the semiconductor devices and materials systems based on heterostructures utilized schemes that allowed the entire structure to be nearly lattice-matched, i.e., no defects are introduced due to the limited strain in the epitaxial layers. Defect engineering in the late 1980s and early 1990s enabled the production of non-lattice-matched heterostructures. Of particular importance in the field of lattice-mismatched epitaxy is the relaxed SiGe on Si substrate heterosystem, which has numerous possibilities for novel device operation from high-speed transistors to integrated optoelectronics.

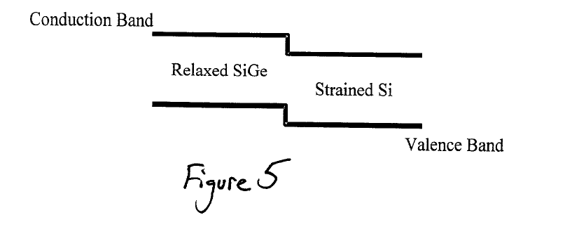

If the SiGe is relaxed, i.e., strain free, and the Si is strained, then the band alignment allows confinement in the conduction band, as shown in FIG. 5. FIG. 5 is a schematic depiction of the band offset for strained Si on relaxed SiGe. When brought to practice, the bandgap misalignment allows for electron confinement in the strained Si layer. The strained Si not only allows electron confinement and the creation of electron gases and channels, but also modifies the Fermi surface.

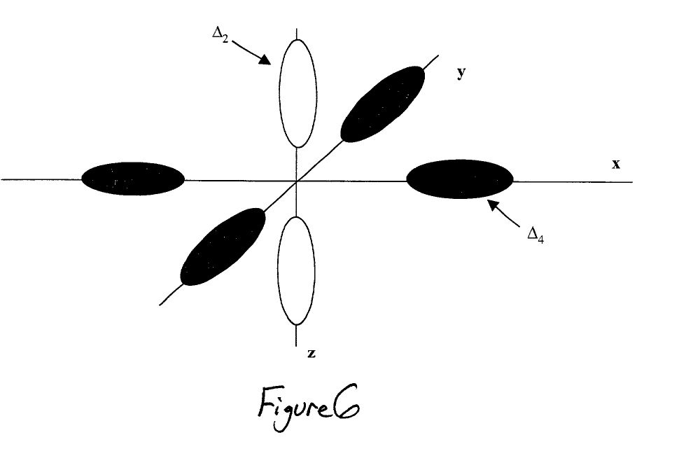

The strain lowers the energy of the two-fold degenerate (Δ₂) out-of-plane valleys with respect to the four-fold degenerate (Δ₄) in-plane valleys. FIG. 6 is a schematic depiction of the conduction band of strained Si. This energy splitting has two effects: 1) only the transverse electron mass is observed during in-plane electron motion due to the lack of longitudinal components in the in-plane valleys, and 2) the intervalley scattering normally experienced in bulk Si is significantly reduced due to the decreased number of occupied valleys.

Until 1991, the experimentally observed electron mobilities were far below the expected values. The low mobilities can be attributed to the relaxed SiGe layer on Si. These early trials used uniform composition SiGe relaxed layers on Si (no compositional grading); therefore, the threading dislocation densities in the carrier channels were >10⁸ cm⁻². This dislocation density causes significant scattering of the carriers, and thus prevents the achievement of high electron mobilities. When advancements in defect engineering are applied to the strained Si/relaxed SiGe heterosystem, high intrinsic mobilities and high mobilities during device operation can be achieved.

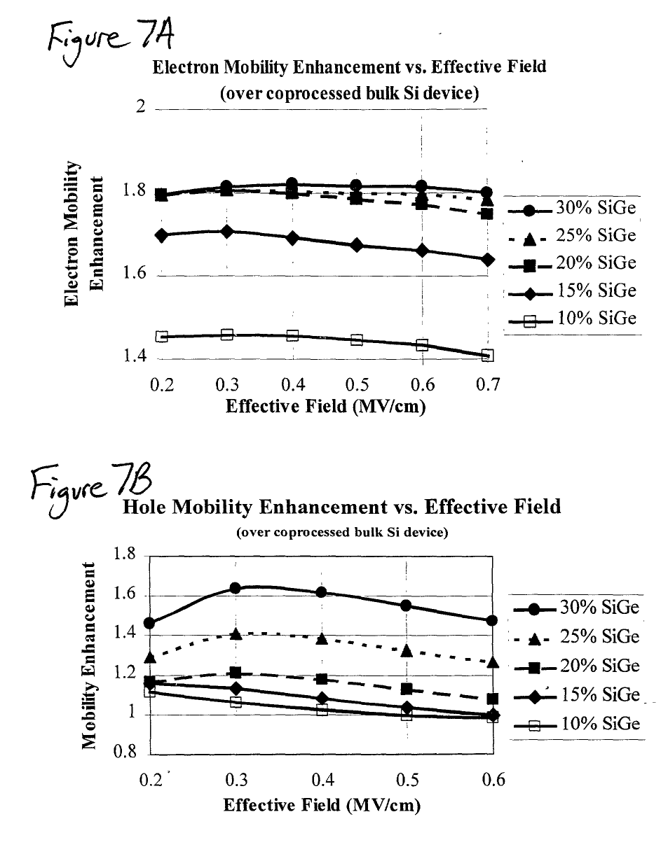

The effects of the Ge concentration in the SiGe layer on electron and hole mobility for a strained Si MOSFET can be seen in FIGS. 7A and 7B, respectively. FIGS. 7A and 7B are graphs showing mobility enhancements vs. effective field for electrons and holes, and for strained silicon on Si₁₋ₓGeₓ for x=10-30%, respectively.

At 20% Ge, the electron enhancement at high fields is approximately 1.75 while the hole enhancement is essentially negligible. When the Ge concentration is increased to 30%, the electron enhancement improves slightly to 1.8 and the hole enhancement rises to about 1.4. The electron enhancement saturates at 20% Ge, where the conduction band splitting is large enough that almost all of the electrons occupy the high mobility band. Hole enhancement saturation has not yet been observed; however, saturation is predicted to occur at a Ge concentration of 40%.

DMOS transistors offer advantages for Si circuitry in analog circuit design. Analog circuit designs make demands on devices and other circuit components that are different from that of digital circuits. For instance, it is imperative that devices used in analog applications have high output impedances, while the opposite is actually true for digital applications. An ideal analog transistor has a high intrinsic gain, high transconductance, and a high cutoff frequency.

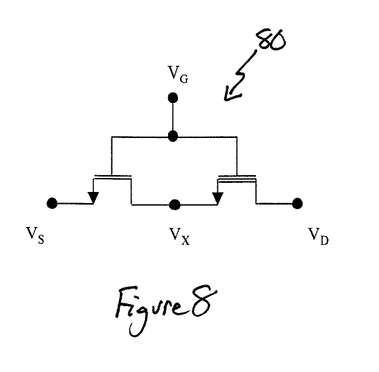

A DMOS transistor can be modeled as an enhancement mode device in series with a depletion mode device. FIG. 8 is a schematic circuit diagram of an enhancement/depletion mode model DMOS transistor 80 in accordance with an exemplary embodiment of the invention. Since devices for analog application are typically operated in the saturation regime, three possible modes of operation can be anticipated: the enhancement mode channel in saturation, the depletion mode channel in saturation, and both the depletion mode and enhancement mode channels in saturation. For best performance, the depletion mode must be in saturation; therefore, the two favorable operating regimes are depletion mode channel saturated, and depletion mode and enhancement mode channels saturated concurrently.

For the case where the depletion mode channel is saturated (assuming no carrier velocity saturation), the transconductance is modeled by the following expression:

$${g}_{m} = \frac{{β}_{e} {β}_{d} ( {V}_{g} - {V}_{x} - {V}_{td} ) ( {V}_{g} - {V}_{te} )}{( {V}_{g} - {V}_{x} ) ( {β}_{e} + {β}_{d} ) - ( {β}_{e} {V}_{te} + {β}_{d} {V}_{td} )}$$

where V_{g} is the applied gate voltage, Vₓ (βₑ, V_{g}, Vₜₑ, β_{d}, V_{td}) is the intermediate voltage between the two devices which is a function in and of itself, V_{td} is the threshold voltage of the depletion mode device, and Vₜₑ is the threshold voltage of the enhancement mode device.

βₑ is the gain in the enhancement mode device and is given by

$${β}_{e} = \frac{{μ}_{e} CW}{{L}_{e}}$$

where μₑ is the mobility of the carriers in the enhancement mode channel, C is the gate capacitance per unit area, W is the width of the channel, and Lₑ is the length of the enhancement mode channel.

β_{d} is the gain in the depletion mode device and is given by

$${β}_{d} = \frac{{μ}_{d} CW}{{L}_{d}}$$

where μ_{d} is the mobility of the carriers in the depletion mode channel and L_{d} is the length of the depletion mode channel.

For the regime where both the depletion mode and enhancement mode devices are saturated, the transconductance is given by

gₘ=βₑ(V_{g}−Vₜₑ)

with the variables defined as above.

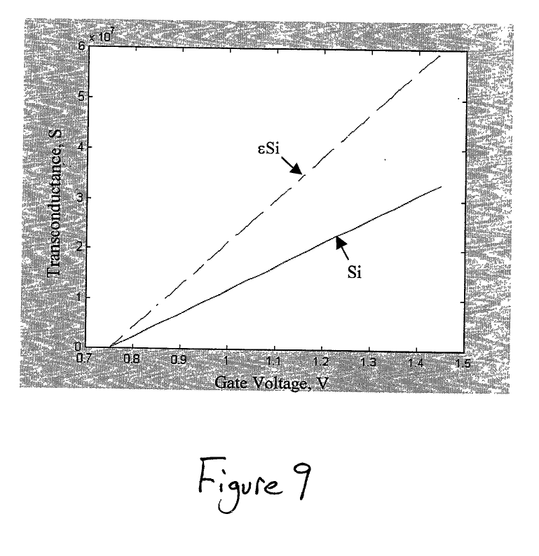

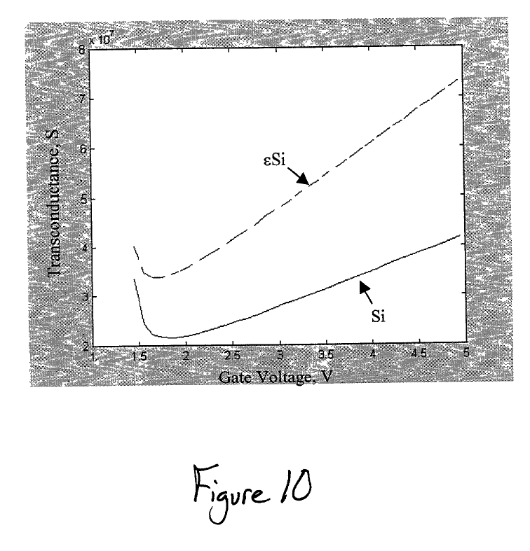

Important characteristics of the DMOS transistor include the channel lengths, the carrier mobilities in each channel (the ratio of the two mobilities as well), and the threshold voltages. These parameters in effect determine terminal and operation characteristics of the device. Using the model and assuming an n-channel DMOS device structure, the impact of the invention can be demonstrated. With V_{td}=0.90 V, Vₜₑ=0.75 V, L_{d}=−0.70×10⁻⁴ cm, Lₑ=0.08×10⁻⁴ cm, μₑ=380 cm²/V-sec, μ_{d}=600 cm²/V-sec, C/W=1 F/cm (for simplicity a value of unity was assumed) and a mobility enhancement factor for electrons in strained Si of 1.8, the transconductance for the two possible regimes of operation are shown in FIGS. 9 and 10.

FIG. 9 is a graph of the transconductance for a LDMOS transistor with strained-Si (ε-Si) and bulk Si with a saturation condition in both the enhancement mode and depletion mode regime. FIG. 9 shows the regime where both the enhancement and depletion mode devices are saturated and there is a straight 80% gain in transconductance through the use of strained Si.

The device operation regime where only the depletion mode device is saturated is shown in FIG. 10. FIG. 10 is a graph of the transconductance for a LDMOS transistor with strained-Si and bulk Si with a saturation condition only in the depletion mode regime. Again, there is an enhancement associated with the use of strained Si. The optimal regime for operation of the device (without carrier velocity saturation) occurs near the boundary of the two regimes where the transconductance is at a maximum. However, the strained Si augments the transconductance of the LDMOS transistor anywhere between 20-80% in the general case. The increased transconductance corresponds to higher operating frequencies and greater ability to drive large capacitive loads, so the invention can provide a substantial benefit to analog device applications.

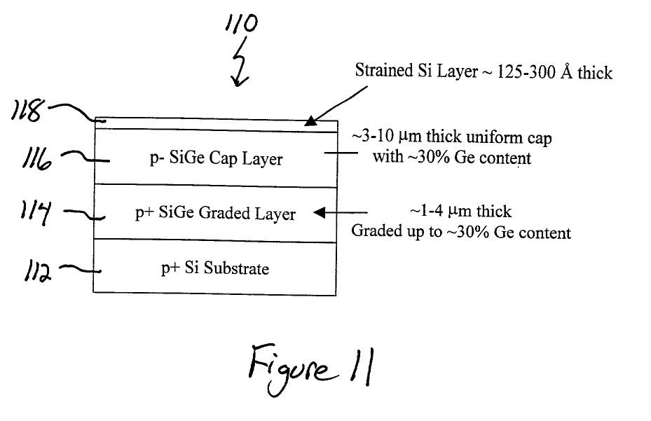

An important aspect of the invention and device performance is the initial epitaxial heterostructure shown in FIG. 11. FIG. 11 is a schematic block diagram of an exemplary embodiment of a strained Si DMOS transistor 110 in accordance with the invention. The processing steps for fabricating such a transistor are as follows: a) bulk substrate 112 cleaning/preparation, b) epitaxial growth of a Si buffer/initiation layer, c) epitaxial growth of a SiGe graded buffer layer 114, d) epitaxial growth of a uniform concentration cap layer 116, and e) epitaxial growth of a strained Si layer 118 below the thickness upon which defects will be introduced to relieve strain (also known as the critical thickness).

The structure of FIG. 11 can also be achieved with a planarization process inserted during an interruption of the epitaxial growth of the uniform composition layer. Although compositional grading allows control of the surface material quality, strain fields due to misfit dislocations in the graded layer can lead to roughness at the surface of the epitaxial layer. If the roughness is severe, it will serve as a pinning site for dislocations and cause a dislocation pileup. An intermediate planarization step removes the surface roughness and thus reduces the dislocation density in the final epitaxial film. The smooth surface provided by planarization also assists in the lithography of the device and enables the production of fine-line features.

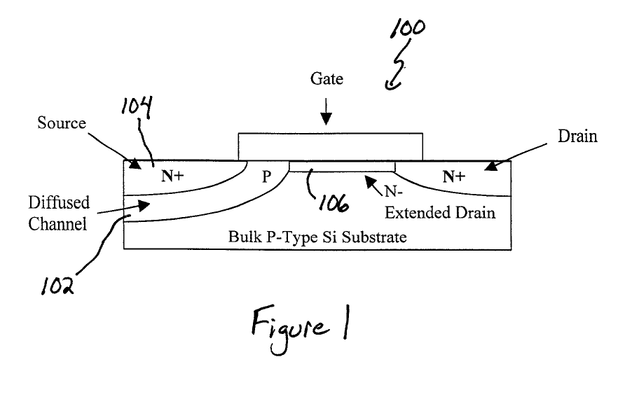

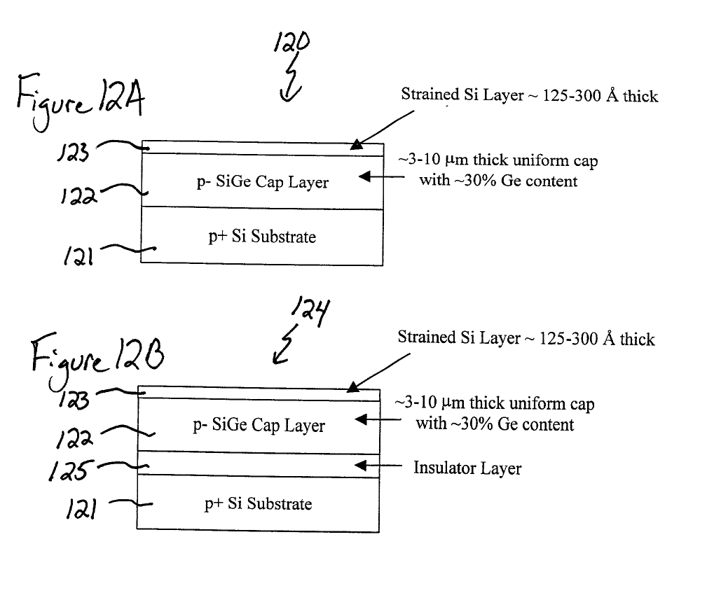

Subsequent processing of the heterostructures leads to alternative embodiments of the invention. FIGS. 12A and 12B are schematic block diagrams of alternative exemplary embodiments of LDMOS transistor structures in accordance with the invention. FIG. 1 2A shows a structure 120 which includes a SiGe cap layer 122 provided directly on a bulk Si substrate 121 surface, with a strained Si epitaxial layer 123 provided on the cap layer. In the exemplary embodiment, the cap layer is, for example, a ˜3-10 μm thick uniform cap layer with ˜30% content, and the strained Si layer ˜25-300Å thick. FIG. 12B shows a similar structure 124 including an insulating layer 125 embedded between the SiGe cap 122 and the bulk Si substrate 121. These substrates are produced by bonding a relaxed SiGe layer to a new Si (or SiO₂ coated Si) substrate, and then subsequently removing the original substrate and graded layer.

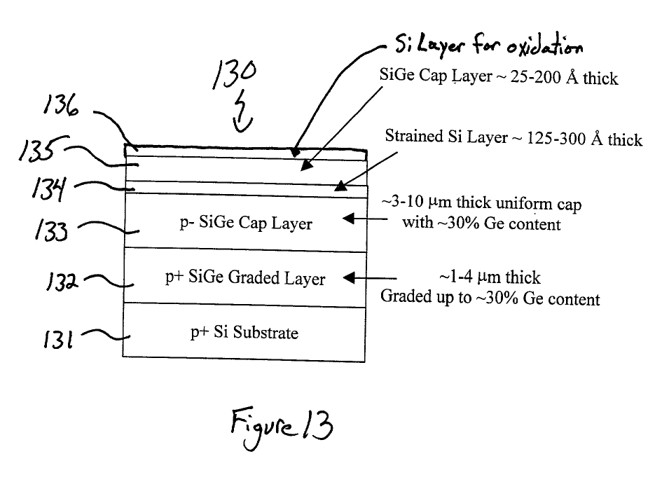

FIG. 13 is a schematic block diagram of an exemplary embodiment of a buried channel LDMOS transistor device structure 130 in accordance with the invention. FIG. 13 shows an initial heterostructure that has the conducting channel spatially separated from the surface via a cap region. In this exemplary embodiment, the charge carrier motion is distanced from the oxide interface, which induces carrier scattering, and thus the device-speed is further improved. The structure 130 includes a Si substrate 131, a SiGe graded layer 132 (˜1-4 μm thick graded up to ˜30% Ge content), a SiGe uniform layer 133 (˜3-10 μm thick with ˜30% Ge content), a strained Si layer 134 (˜25-300Å thick), a SiGe cap layer 135 (˜25-200Å thick), and a second strained Si layer 136 (˜25-200Å thick).

The second Si layer 136 is used to form the gate oxide of the device. When SiGe alloys are oxidized with conventional techniques, such as thermal oxidation, an excessive number of interfacial surface states are created, typically in excess of 10¹³ cm⁻². In order to overcome this problem, a sacrificial Si oxidation layer is introduced into the heterostructure. The oxidation of this layer is carefully controlled to ensure that approximately 5-15< of Si remains after oxidation. Since the oxide interface is in the Si and not the SiGe, the interfacial state density remains low, i.e., 10¹⁰-10¹¹ cm⁻², and device performance is not compromised.

Although the present invention has been shown and described with respect to several preferred embodiments thereof, various changes, omissions and additions to the form and detail thereof, may be made therein, without departing from the spirit and scope of the invention.

What is claimed is:

1. A heterostructure for a diffused metal oxide semiconductor (DMOS) transistor comprising:
a monocrystalline Si substrate;
a relaxed SiGe uniform composition layer on said substrate; and
a strained-Si channel layer on said uniform composition layer.

2. The heterostructure of claim 1, wherein a compositionally graded SiGe epitaxial layer is positioned between said Si substrate and said uniform composition layer.

3. The heterostructure of claim 1, wherein said strained-Si channel layer is spatially separated from the surface of the heterostructure.

4. The heterostructure of claim 3, wherein a semiconductor layer is provided on said strained-Si channel layer such that said strained-Si channel layer is buried below the surface of the heterostructure.

5. The heterostructure of claim 1, wherein an insulator is imbedded in between said strained-Si channel layer and said substrate.

6. The heterostructure of claim 1, wherein said relaxed SiGe layer is planarized prior to application of said strained-Si channel.

7. An integrated circuit comprising a heterostructure for a diffused metal oxide semiconductor (DMOS) transistor, said heterostructure comprising a monocrystalline Si substrate, a relaxed SiGe uniform composition layer on said substrate, and a strained-Si channel layer on said uniform composition layer.

8. The integrated circuit of claim 7, wherein a compositionally graded SiGe epitaxial layer is positioned between said Si substrate and said uniform composition layer.

9. The integrated circuit of claim 7, wherein said strained-Si channel layer is spatially separated from the surface of the heterostructure.

10. The integrated circuit of claim 9, wherein a semiconductor layer is provided on said strained-Si channel layer such that said strained-Si channel layer is buried below the surface of the heterostructure.

11. The integrated circuit of claim 7, wherein an insulator is imbedded in between said strained-Si channel layer and said substrate.

12. The integrated circuit of claim 7, wherein said relaxed SiGe layer is planarized prior to application of said strained-Si channel.

13. A heterostructure for a diffused metal oxide semiconductor (DMOS) transistor comprising:
a monocrystalline Si substrate;
a relaxed SiGe uniform composition layer on said substrate;
a first strained-Si channel layer on said uniform composition layer;
a SiGe cap layer on said strained-Si channel layer; and
a second strained-Si layer on said cap layer.

14. The heterostructure of claim 13, wherein a compositionally graded SiGe epitaxial layer is between said Si substrate and said uniform composition layer.

15. The heterostructure of claim 13, wherein an insulator layer is imbedded in between said strained-Si channel layer and said substrate.

16. The heterostructure of claim 13, wherein said relaxed SiGe layer is planarized prior to application of said strained-Si channel layer.

17. An integrated circuit comprising a heterostructure for a diffused metal oxide semiconductor (DMOS) transistor, said heterostructure comprising a monocrystalline Si substrate, a relaxed SiGe uniform composition layer on said substrate, a first strained-Si channel layer on said uniform composition layer, a SiGe cap layer on said strained-Si channel layer and a second strained-Si layer on said cap layer.

18. The integrated circuit of claim 17, wherein a compositionally graded SiGe epitaxial layer is between said Si substrate and said uniform composition layer.

19. The integrated circuit of claim 17, wherein an insulator layer is imbedded in between said strained-Si channel layer and said substrate.

20. The integrated circuit of claim 17, wherein said relaxed SiGe layer is planarized prior to application of said strained-Si channel layer.

21. A method of fabricating a heterostructure for a diffused metal oxide semiconductor (DMOS) transistor comprising:
providing a monocrystalline Si substrate;
applying a relaxed SiGe uniform composition layer on said substrate; and
applying a strained-Si channel layer on said uniform composition layer.

22. A method of fabricating a heterostructure for a diffused metal oxide semiconductor (DMOS) transistor comprising:
providing a monocrystalline Si substrate;
applying a compositionally graded SiGe epitaxial layer on said substrate;
applying a uniform composition SiGe cap layer on said graded layer; and
applying a strained-Si channel layer on said cap layer.

23. A method of fabricating a heterostructure for a diffused metal oxide semiconductor (DMOS) transistor comprising:
providing a monocrystalline Si substrate;
applying a relaxed SiGe uniform composition layer on said substrate;
applying a first strained-Si channel layer on said uniform composition layer;
applying a SiGe cap layer on said strained-Si channel layer; and
applying a second strained-Si layer on said cap layer.

24. A method of fabricating a heterostructure for a diffused metal oxide semiconductor (DMOS) transistor comprising:
providing a monocrystalline Si substrate;
applying a compositionally graded SiGe epitaxial layer on said substrate;
applying a uniform composition SiGe layer on said graded layer;
applying a first strained-Si channel layer on said uniform composition SiGe layer;
applying a SiGe cap layer on said strained-Si channel layer; and
applying a second strained-Si layer on said cap layer.
